(19) United States
(12) Patent Application Publication
(10) Pub. No.: US 2025/0067824 A1
(43) Pub. Date: Feb. 27, 2025

(54) MULTI-ROW MAGNETIC RESONANCE IMAGING (MRI) RADIO FREQUENCY (RF) COIL WITH A DECOUPLING RING

(71) Applicant: Quality Electrodynamics, LLC, Mayfield Village, OH (US)

(72) Inventors: Xiaoyu Yang, Indiana, PA (US); Alexander Smerglia, Cleveland, OH (US); Tsinghua Zheng, Chesterland, OH (US); Labros Petropoulos, Chardon, OH (US)

(21) Appl. No.: 18/809,559

(22) Filed: Aug. 20, 2024

Related U.S. Application Data
(60) Provisional application No. 63/578,707, filed on Aug. 25, 2023.

(51) Int. Cl. G01R 33/34; G01R 33/3415; G01R 33/36

(52) U.S. Cl. CPC G01R 33/34007; G01R 33/3415; G01R 33/365

(57) ABSTRACT

The present disclosure provides a magnetic resonance imaging (MRI) radio frequency (RF) coil that has a discontinuous cylindrical-like shape and that has a decoupling ring enhanced to accommodate a discontinuity in the discontinuous cylindrical-like shape without use of electrical connectors. As seen hereafter, such enhancement allows the decoupling ring to extend in a closed path fully within the discontinuous cylindrical-like shape, which may, for example, be a U shape, a C shape, or some other suitable shape.

### REFERENCE TO RELATED APPLICATION

This application claims the benefit of U.S. Provisional Application No. 63/578,707, filed on Aug. 25, 2023, the contents of which are incorporated by reference in their entirety.

### BACKGROUND

Magnetic resonance imaging (MRI) involves the transmission and receipt of radio frequency (RF) energy. RF energy may be transmitted by an RF coil to create a B₁ field that rotates a net magnetization. Further, resulting magnetic resonance (MR) signals may be received by an RF coil to detect precessing transverse magnetization. Thus, RF coils may be transmit (Tx) coils, receive (Rx) coils, or transmit and receive (Tx/Rx) coils.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a diagram of some embodiments of a multi-row magnetic resonance imaging (MRI) radio frequency (RF) coil with a decoupling ring.

FIG. 2 illustrates a diagram of some embodiments of a feed board of the multi-row MRI RF coil of FIG. 1.

FIGS. 3A-3D illustrate simplified diagrams of some embodiments of a pair of directly neighboring RF coil elements in the multi-row MRI RF coil of FIG. 1.

FIGS. 4A and 4B illustrate simplified diagrams of some embodiments of a pair of non-directly neighboring RF coil elements in the multi-row MRI RF coil of FIG. 1.

FIG. 5 illustrates a more detailed diagram of some embodiments of the multi-row MRI RF coil of FIG. 1 in which feed boards are as in FIG. 2.

FIG. 6 illustrates a diagram of some alternative embodiments of the multi-row MRI RF coil of FIG. 1 in which the decoupling ring is at a periphery of the multi-row MRI RF coil.

FIG. 7 illustrates a diagram of some alternative embodiments of the multi-row MRI RF coil of FIG. 1 in which overlap decoupling is employed within a row.

FIG. 8 illustrates a diagram of some alternative embodiments of the multi-row MRI RF coil of FIG. 1 in which the multi-row MR RF coil has additional RF coil elements.

FIGS. 9A and 9B illustrate various diagrams of some embodiments of a U-shaped former on which the multi-row MRI RF coil of FIG. 8 is arranged.

FIG. 10 illustrates an axial diagram of some embodiments of a C-shaped former on which the multi-row MRI RF coil of FIG. 8 is arranged.

FIG. 11 illustrates an axial diagram of some embodiments of an O-shaped former on which the multi-row MRI RF coil of FIG. 8 is arranged.

FIG. 12 illustrates a diagram of some alternative embodiments of the multi-row MRI RF coil of FIG. 8 in which the decoupling ring is at a periphery of the multi-row MRI RF coil.

FIG. 13 illustrates a diagram of some alternative embodiments of the multi-row MRI RF coil of FIG. 8 in which a first row of the multi-row MRI RF coil is offset from a second row of the multi-row MRI RF coil along a length of the first row.

FIG. 14 illustrates a diagram of some alternative embodiments of the multi-row MRI RF coil of FIG. 8 in which the decoupling ring spans fewer than all RF coil elements.

FIGS. 15A and 15B illustrate various diagrams of some alternative embodiments of the multi-row MRI RF coil of FIG. 8 in which the multi-row MRI RF coil has three rows.

FIG. 16 illustrates a diagram of some alternative embodiments of the multi-row MRI RF coil of FIG. 8 in which the multi-row MRI RF coil has four rows and the decoupling ring spans fewer than all rows.

FIG. 17 illustrates a diagram of some alternative embodiments of the multi-row MRI RF coil of FIG. 8 in which the multi-row MRI RF coil corresponds to a foot-ankle coil.

FIG. 18 illustrates a perspective diagram of some embodiments of a foot-ankle former on which the multi-row MRI RF coil of FIG. 17 is arranged.

FIGS. 19A and 19B illustrate various diagrams of some embodiments of an MRI system comprising a multi-row MRI RF coil RF coil with a decoupling ring.

FIG. 20 illustrates a block diagram of some embodiments of a method for MRI in accordance with some aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purposes of simplicity and clarity and does not in itself dictate a relationship between the various embodiments and/or configurations discussed.

Further, spatially relative terms, such as “beneath,” “below,” “lower,” “above,” “upper,” “lower,” and the like, may be used herein for ease of description to describe one element or feature's relationship to one or more other elements or features as illustrated in the figures. The spatially relative terms are intended to encompass different orientations of the device in use or operation in addition to the orientation depicted in the figures. The apparatus may be otherwise oriented (e.g., rotated 90 degrees or at other orientations), and the spatially relative descriptors used herein may likewise be interpreted accordingly.

Phased array technology is an approach to build a multi-channel magnetic resonance imaging (MRI) radio frequency (RF) coil. It has the advantage of providing the signal penetration of a large coil while also providing the high signal performance of a small coil at a shallow depth. The multi-channel MRI RF coil comprises multiple coil elements that are arranged in one or more rows and that correspond to channels.

The coil elements may couple (e.g., inductively couple) to each other and negatively impact signal-to-noise ratio (SNR), whereby minimizing the couplings between coil elements is important. The couplings result in multiple orders of noise. Zero order noise corresponds to noise from signals induced in coil elements by the scan object, whereas first order noise corresponds to noise from signals induced in coil elements by other coil elements.

First order noise may be reduced by preamplifier decoupling. Preamplifier decoupling uses low input impedance preamplifiers to reduce current flow in coil elements. This reduces signals induced in coil elements by other coil elements and hence reduces first order noise. Zero and first order noise may be reduced by minimizing or otherwise canceling mutual inductance between coil elements. Directly neighboring coil elements may be overlapped to minimize mutual inductance and/or may share a decoupling capacitor to cancel mutual inductance. However, these decoupling approaches are limited to directly neighboring coil elements. Other decoupling approaches that can account for non-directly neighboring coil elements include a capacitor ladder approach and a decoupling ring approach.

The capacitor ladder approach is only suitable for decoupling as many as nine coil elements. For example, if the number of coil elements exceeds nine (e.g., more than twelve), and the coil elements are arranged in multiple rows (e.g., two rows and above) extending circumferentially around a cylindrical-like former, the large number of coil pairs make it difficult to use the capacitor ladder approach to decouple all coil elements. The decoupling ring approach may be used for a larger numbers of coil elements (e.g., nine, twelve, or more coil elements) than the capacitor ladder approach. Hence, continuing with the above example, the decoupling ring approach may be used in place of the capacitor ladder approach.

A challenge with the decoupling ring approach and the capacitor ladder approach is that these approaches depend on a decoupling ring or a capacitor ladder having continuous electrical connectivity circumferentially around an imaging volume. If the multiple-channel MRI RF coil has a continuous cylindrical-like shape, the continuous electrical connectivity is not a problem. However, if the multiple-channel MRI RF coil has a discontinuous cylindrical-like shape, the continuous electrical connectivity may only be achieved by bridging discontinuities using electrical connectors that are connected and disconnected with each use of the coil. Such connecting and disconnecting introduces workflow inefficiencies.

The present disclosure provides an MRI RF coil that has a discontinuous cylindrical-like shape and that has a decoupling ring enhanced to accommodate a discontinuity in the discontinuous cylindrical-like shape without use of electrical connectors. As seen hereafter, such enhancement allows the decoupling ring to extend in a closed path fully within the discontinuous cylindrical-like shape. The discontinuous cylindrical-like shape may, for example, be a U shape, a C shape, an O shape, or some other suitable shape. Note that an O-shaped coil extends circumferentially around an imaging volume from a first end of the O-shaped coil to a second end of the O-shaped coil that is disconnected from the first end.

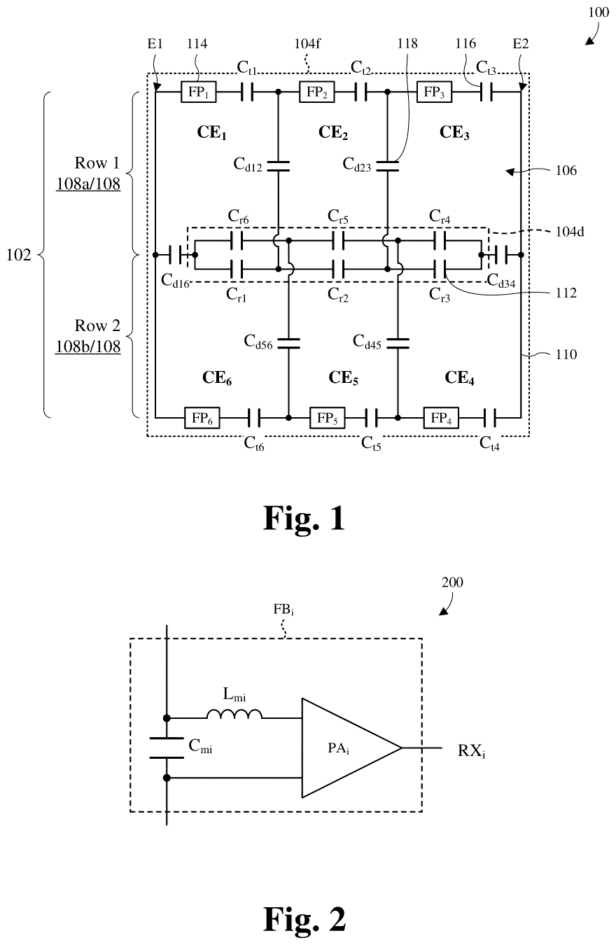

With reference to FIG. 1, a diagram 100 of some embodiments of a multi-row MRI RF coil 102 with a decoupling ring 104d according to aspects of the present disclosure is provided. The multi-row MRI RF coil 102 is flattened for case of illustration. However, in practice, the multi-row MRI RF coil 102 has a discontinuous cylindrical-like shape extending circumferentially around an imaging volume, from a first end E1 of the multi-row MRI RF coil 102 to a second end E2 of the multi-row MRI RF coil 102.

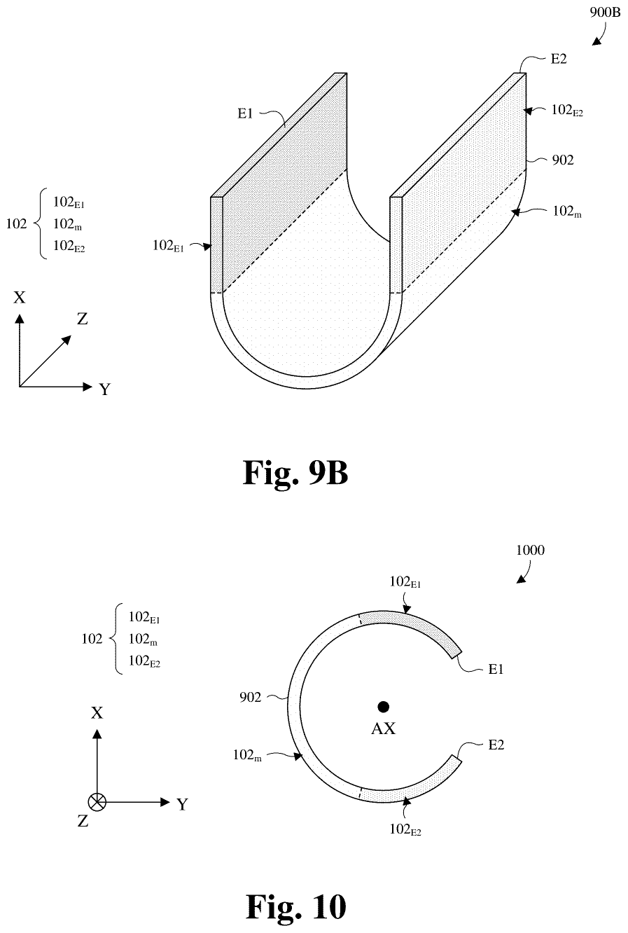

The second end E2 is disconnected and spaced from the first end E1. There are no electrical connectors to provide electrical connectivity from the first end E1 to the second end E2. Further, a discontinuity in the discontinuous cylindrical-like shape may, for example, separate the first end E1 from the second end E2. The discontinuous cylindrical-like shape may, for example, be a U shape, a C shape, an O shape, or some other suitable shape. FIGS. 9A, 9B, 10, and 11 provide non-limiting examples of such shapes.

The multi-row MRI RF coil 102 comprises a plurality of RF coil elements 106 in a plurality of rows 108, including a first row 108a and a second row 108b. The plurality of rows 108 extend in parallel, or generally in parallel, from the first end E1 of the multi-row MRI RF coil 102 to the second end E2 of the multi-row MRI RF coil 102. Further, the plurality of rows 108 overlap to reduce inductive coupling therebetween. In alternative embodiments, there is no overlap between the plurality of rows 108 and/or there are more rows.

The plurality of rows 108 each has at least two RF coil elements. For example, as illustrated, the plurality of rows 108 may each have three RF coil elements. Further, the plurality of rows 108 share a common number of RF coil elements. For example, as illustrated, the plurality of rows 108 may both have three RF coil elements. In alternative embodiments, the plurality of rows 108 may have different numbers of RF coil elements.

The plurality of RF coil elements 106 correspond to receive and/or transmit RF channels and are individually labeled CEᵢ, where i is an integer index from 1 to N and N is a total number of the plurality of RF coil elements 106. The plurality of RF coil elements 106 are formed in part by a plurality of conductive traces 110 that are arranged in loops and that define, or mostly define, individual inductances of the plurality of RF coil elements 106. Further, the plurality of RF coil elements 106 are formed in part by a plurality of ring capacitors 112, a plurality of feed boards 114, a plurality of tuning capacitors 116, and a plurality of decoupling capacitors 118 that are on and electrically coupled respectively to the loops.

The plurality of ring capacitors 112, the plurality of feed boards 114, and the plurality of tuning capacitors 116 are individual to the plurality of RF coil elements 106. The plurality of ring capacitors 112 are individually labeled Cᵣᵢ, the plurality of feed boards 114 are individually labeled FPᵢ, and the plurality of tuning capacitors 116 are individually labeled Cₜᵢ, where i is an integer index for the corresponding RF coil element.

The plurality of ring capacitors 112 form the decoupling ring 104d and have individual capacitance values selected, as explained hereafter, to minimize mutual inductance between directly and non-directly neighboring RF coil element. Each of the plurality of ring capacitors 112 is between and electrically coupled directly to two other ring capacitors. Further, each of the plurality of ring capacitors 112 is representative of one or more capacitors electrically coupled in series and on the loop of a corresponding RF coil element.

In alternative embodiments, each of the plurality of ring capacitors 112 may be replaced with a ring inductor or a series combination of a ring capacitor and a ring inductor. Similar to a ring capacitor, a ring inductor may be representative of one or more inductors electrically coupled in series and on the loop of a corresponding RF coil element. Accordingly, the plurality of ring capacitors 112 may more generally be referred to as reactive ring elements and may be replaced with one or more capacitors and/or one or more inductors electrically coupled in series and on the loop of the corresponding RF coil element.

The decoupling ring 104d is formed at an overlap between the plurality of rows 108 and is spaced from the first and second ends E1, E2 of the of the multi-row MRI RF coil 102. Further, the decoupling ring 104d extends in a continuous closed path entirely within a shape or layout of the multi-row MRI RF coil 102. As such, the decoupling ring 104d is not dependent on electrical connectors to provide electrical connectivity between the first and second ends E1, E2. By not having to connect and disconnect the first and second ends E1, E2 during use of the multi-row MRI RF coil 102, workflow efficiencies may be gained.

The plurality of feed boards 114 provide connection points for electrically connecting the plurality of RF coil elements 106 to receivers and/or transmitters. For example, the plurality of feed boards 114 may be electrically coupled to receivers for use of the multi-row MRI RF coil 102 as a phase array receive coil. As another example, the plurality of feed boards 114 may be electrically coupled to transmitters for use of the multi-row MRI RF coil 102 as a parallel transmit (pTx) coil. As yet another example, the plurality of feed boards 114 may be electrically selectively coupled to receivers and transceivers via transmit/receive (TR) switches for use of the multi-row MRI RF coil 102 as both a phase array receive coil and pTx coil.

The plurality of tuning capacitors 116 resonant respectively with the individual inductances of the plurality of RF coil elements 106 at a resonant working frequency, such as a Larmar frequency, and facilitate tuning of the resonant frequency. As noted above, the inductances of the plurality of RF coil elements 106 result from the plurality of conductive traces 110. Further, each of the plurality of tuning capacitors 116 is representative of one or more capacitors on the loop of a corresponding RF coil element.

In alternative embodiments, each of the plurality of tuning capacitors 116 may be replaced with a tuning inductor or a series combination of a tuning capacitor and a tuning inductor. Similar to a tuning capacitor, a tuning inductor may be representative of one or more inductors electrically coupled in series and on the loop of a corresponding RF coil element. Accordingly, the plurality of tuning capacitors 116 may more generally be referred to as reactive tuning elements and may be replaced with one or more capacitors and/or one or more inductors electrically coupled in series and on the loop of the corresponding RF coil element.

The plurality of feed boards 114 and the plurality of tuning capacitors 116 are on a feed ring 104f formed by corresponding conductive traces. The feed ring 104f extends in a continuous closed path along a periphery of the of the multi-row MRI RF coil 102 to completely surround the decoupling ring 104d and the plurality of RF coil elements 106. Further, the feed ring 104f is spaced from the decoupling ring 104d. In alternative embodiments, locations of the feed ring 114f and the decoupling ring 104d are switched.

The plurality of decoupling capacitors 118 correspond to pairs of RF coil elements that directly neighbor along the feed ring 104f. Further, each of the plurality of decoupling capacitors 118 is shared by the corresponding pair of RF coil elements and minimizes mutual inductance between the corresponding pair of RF coil elements. The plurality of decoupling capacitors 118 are individually labeled C_{dij}, where i and j are integer indexes for the RF coil elements of the corresponding pairs of RF coil elements.

Each of the plurality of decoupling capacitors 118 is representative of one or more capacitors on a shared conductive trace for loops of corresponding RF coil elements. In alternative embodiments, each of the plurality of decoupling capacitors 118 may be replaced with a decoupling inductor or a series combination of a decoupling capacitor and a decoupling inductor. Similar to a decoupling capacitor, a decoupling inductor may be representative of one or more inductors electrically coupled in series and on a shared conductive trace for loops of corresponding RF coil elements. Accordingly, the plurality of decoupling capacitors 118 may more generally be referred to as reactive decoupling elements and may be replaced with one or more capacitors and/or one or more inductors electrically coupled in series and on the shared conductive trace for loops of corresponding RF coil elements.

In some embodiments, the multi-row MRI RF coil 102 is fully rigid. In other embodiments, the multi-row MRI RF coil 102 is flexible at the first and second ends E1, E2 and otherwise rigid. This may allow the multi-row MRI RF coil 102 to be changed between an open and closed state to facilitate easy loading of a scan object and sizing of the multi-row MRI RF coil 102 around the scan object. For example, the multi-row MRI RF coil 102 may be flexible at the first and second ends E1, E2 to accommodate different knee sizes and improve comfort. The same flexible approach may also be used for a wrist anatomy, a shoulder anatomy, a foot and/or ankle anatomy, a leg anatomy, an arm anatomy, and so on.

In some embodiments, the plurality of conductive traces 110 are formed by coaxial cable, copper strips or sheets, or the like. Further, while each of the plurality of conductive traces 110 are illustrated as either vertical or horizontal in FIG. 1, the plurality of conductive traces 110 may also be tilted (e.g., between vertical and horizontal) for improved SNR at the overlapping area between the plurality of rows 108. In some embodiments, the vertical direction in FIG. 1 corresponds to the B₀ field direction, whereas the horizontal direction in FIG. 1 corresponds to a circumferential direction around an imaging volume.

With reference to FIG. 2, a diagram 200 of some embodiments of a feed board FPᵢ of the multi-row MRI RF coil 102 of FIG. 1 is provided. The feed board FPᵢ is representative of each of the plurality of feed boards 114 and i corresponds to an integer index for a corresponding one of the plurality of RF coil elements 106 in FIG. 1.

Note that if the multi-row MRI RF coil 102 is a receive coil, the multi-row MRI RF coil 102 may have decoupling circuits for decoupling the multi-row MRI RF coil 102 from a transmit coil of an MRI system during a transmit mode of the MRI system. Further, note that if the multi-row MRI RF coil 102 is a transmit/receive coil, the multi-row MRI RF coil 102 may have transmit/receive (T/R) switching circuits. However, since the aforementioned circuits are not relevant to the disclosure, they are omitted in the rest of the description and discussion.

The feed board FPᵢ comprises a matching capacitor Cₘᵢ, a matching inductor Lₘᵢ, and a low input impedance preamplifier PAᵢ. The preamplifier PAᵢ has a low input impedance and outputs a receive signal RX; at an output terminal during use of the preamplifier PAᵢ. Further, the preamplifier PAᵢ has a first input terminal electrically coupled to a first terminal of the matching capacitor Cₘᵢ by the matching inductor Lₘᵢ and a second input terminal electrically coupled to a second terminal of the matching capacitor Cₘᵢ. Because the preamplifier PAᵢ has a low input impedance, the matching capacitor Cₘᵢ and the matching inductor Lₘᵢ are effectively coupled in parallel and resonate with each other during use of the preamplifier PAᵢ.

Values of the matching capacitor Cₘᵢ and the matching inductor Lₘᵢ are selected so the matching capacitor Cₘᵢ and the matching inductor Lₘᵢ resonant at the working frequency of the multi-row MRI RF coil 102, such as a Larmor frequency. During use of the multi-row MRI RF coil 102, this resonance creates a high impedance that minimizes current flow in an RF coil element and reduces first order noise induced in other RF coil elements.

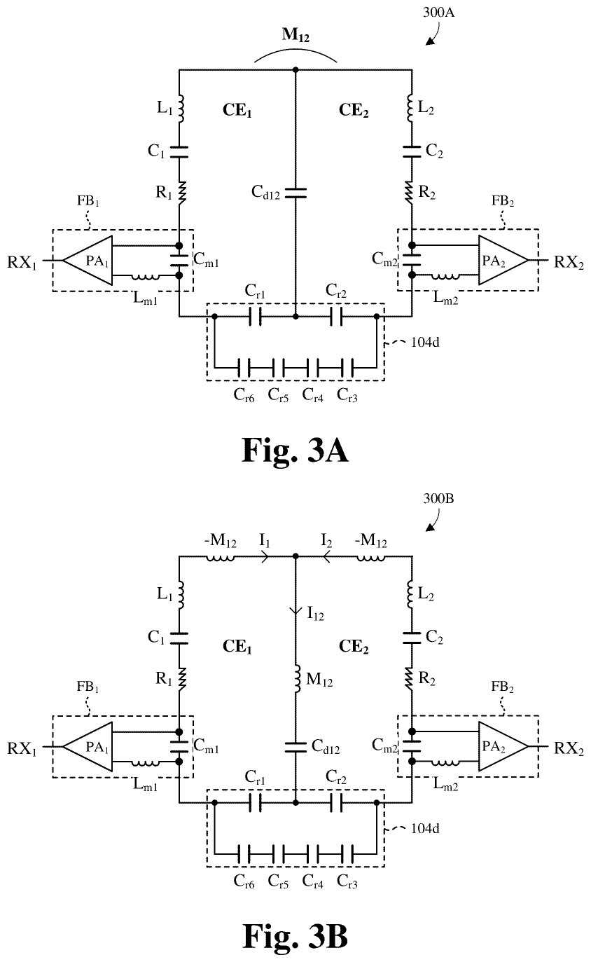

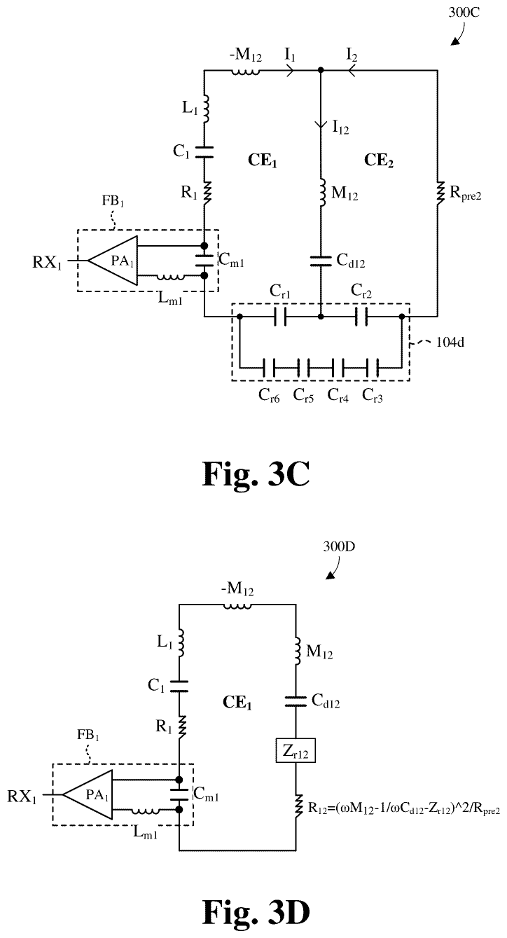

With reference to FIGS. 3A-3D, simplified diagrams 300A-300D of some embodiments of a pair of directly neighboring RF coil elements CE₁, CE₂ in the multi-row MRI RF coil 102 of FIG. 1 are provided to illustrate decoupling of the pair of the directly neighboring RF coil elements. While RF coil element CE₁ and RF coil element CE₂ are illustrated, other directly neighboring RF coil elements are amenable.

Focusing on FIG. 3A, RF coil element CE₁ comprises ring capacitor Cᵣ₁ on the decoupling ring 104d, as well as inductor L₁, capacitor C₁, resistor R₁, and feed board FB₁. Inductor L₁ may correspond to inductance of conductive traces of RF coil element CE₁. Capacitor C₁ may correspond to tuning capacitor Cₜ₁ in FIG. 1. Resistor R₁ may correspond to coil loss, which may include, for example, conductive-trace loss, phantom loss, and RF radiation loss. Feed board FB₁ is configured to output receive signal RX₁ and may, for example, be as its counterpart is described with regard to FIG. 2. Further, feed board FB₁ comprises matching capacitor Cₘ₁, matching inductor Lₘ₁, and preamplifier PA₁.

RF coil element CE₂ is similar to RF coil element CE and comprises capacitor Cᵣ₂ on the decoupling ring 104d, as well as inductor L₂, capacitor C₂, resistor R₂, and feed board FB₂. Inductor L₂ may correspond to inductance of conductive traces of RF coil element CE₂. Capacitor C₂ may correspond to tuning capacitor Cₜ₂ in FIG. 1. Resistor R₂ may correspond to coil loss. Feed board FB₂ is configured to output receive signal RX₂ and may, for example, be as its counterpart is described with regard to FIG. 2. Further, feed board FB₂ comprises matching capacitor Cₘ₂, matching inductor Lₘ₂, and preamplifier PA₂.

RF coil element CE₁ and RF coil element CE₂ are coupled by mutual inductance M₁₂ and share decoupling capacitor C_{d12}. As seen hereafter, decoupling capacitor C_{d12} and the decoupling ring 104d are tuned to minimize or negate mutual inductance M₁₂.

Focusing on FIG. 3B, current in a loop of RF coil element CE₁ is deemed I₁ and current in a loop of RF coil element CE₂ is deemed I₂, whereby current at the shared conductive trace between RF coil element CE₁ and RF coil element CE₂ is deemed I₁₂=I₁+I₂. Further, using Kirchhoff's law while ignoring the decoupling ring 104d yields Eq. 1, where ω is the angular frequency. Note that the decoupling ring 104d is ignored for simplicity and since it doesn't change the outcome hereafter described.

$$\{ \begin{matrix}{I}_{1} ( j ω {L}_{1} - j \frac{1}{ω {C}_{1}} + {R}_{1} ) + j ω {M}_{12} {I}_{2} - j \frac{1}{ω {C}_{d 12}} {I}_{12} = 0 \\ {I}_{2} ( j ω {L}_{2} - j \frac{1}{ω {C}_{2}} + {R}_{2} ) + j ω {M}_{12} {I}_{1} - j \frac{1}{ω {C}_{d 12}} {I}_{12} = 0\end{matrix} \qquad Eq . 1$$

By adding jωM₁₂I₁−jωM₁₂I₁ (nets zero) to the equation portion for RF coil element CE₁, and by adding jωM₁₂I₂-jωM₁₂I₂ (nets to zero) to the equation portion for RF coil element CE₂, Eq. 1 may be simplified as shown in Eq. 2.

$$\{ \begin{matrix}{I}_{1} ( j ω {L}_{1} - j ω {M}_{12} - j \frac{1}{ω {C}_{1}} + {R}_{1} ) + j ω {M}_{12} {I}_{12} - j \frac{1}{ω {C}_{d 12}} {I}_{12} = 0 \\ {I}_{2} ( j ω {L}_{2} - j ω {M}_{12} - j \frac{1}{ω {C}_{2}} + {R}_{2} ) + j ω {M}_{12} {I}_{12} - j \frac{1}{ω {C}_{d 12}} {I}_{12} = 0\end{matrix} \qquad Eq . 2$$

Based on Eq. 2, it's seen that mutual inductance M₁₂ from FIG. 3A may be represented as inductors −M₁₂ on the individual loops of RF coil element CE₁ and RF coil element CE₂. Further, mutual inductance M₁₂ may be added as an inductor M₁₂ on the shared conductive trace between RF coil element CE₁ and RF coil element CE₂.

Focusing on FIGS. 3B and 3C, elements of RF coil element CE₂ may be simplified to high preamplifier resistance Rₚᵣₑ₂. Inductor L₂, capacitor C₂, and inductor-M₁₂ of RF coil element CE₂ resonant together in series during use of RF coil element CE₂. Such in series resonance may be at a Larmor frequency or some other suitable working frequency. Because of this series resonance, these elements have a combined impedance of zero and may be ignored. Additionally, because preamplifier PA₂ is a low input impedance preamplifier, and because matching capacitor Cₘ₂ and matching inductor Lₘ₂ resonant together in parallel, feed board FB₂ may be replaced with high preamplifier resistance Rₚᵣₑ₂. Because high preamplifier resistance Rₚᵣₑ₂ is significantly higher than resistance R₂, resistance R₂ may be ignored.

Focusing on FIGS. 3C and 3D, the decoupling ring 104d may be simplified or otherwise approximated as ring impedance Zᵣ₁₂ shared between RF coil element CE₁ and RF coil element CE₂. Note that this may yield additional impedances individual to RF coil element CE₁ and RF coil element CE₂. However, these additional impedances are ignored for simplicity since they don't affect the outcome hereafter described.

High preamplifier resistance Rₚᵣₑ₂ is additionally transformed from being in parallel with the shared conductive trace to being in series with the shared conductive trace using Q factors. Particularly, assume a reactive element (e.g., capacitor or inductor) has a Q greater than five, as is likely to be the case for the multi-row MRI RF coil. A reactive element in series with a resistance has a Q=Z/Rₛ, where Z is an impedance of the reactive element and Rₛ is the series resistance. Similarly, a reactive element in parallel with a resistance has a Q=Rₚ/Z, where Z is an impedance of the reactive element and Rₚ is the parallel resistance. Setting the above two equations equal to each other

$$( e . g . , \frac{{R}_{p}}{Z} = \frac{Z}{{R}_{s}} )$$

and simplifying yields Eq. 3.

$${R}_{s} = \frac{{Z}^{2}}{{R}_{P}} \qquad Eq . 3$$

Because inductor M₁₂, ring impedance Zᵣ₁₂, and decoupling capacitor C_{d12} are all reactive elements and are collectively in parallel with high preamplifier resistance Rₚᵣₑ₂, these elements can be applied to Eq. 3 to transform high preamplifier resistance Rₚᵣₑ₂ to resistance R₁₂. This is seen through reference below to Eq. 4.

$${R}_{12} = \frac{{( ω {M}_{12} - \frac{1}{ω {C}_{d 12}} - {Z}_{r 12} )}^{2}}{{R}_{pre 2}} \qquad Eq . 4$$

Focusing on FIG. 3D, it can be seen that decoupling capacitor C_{d12} and ring impedance Zᵣ₁₂ (e.g., via the plurality of decoupling capacitors 118) may be tuned to reduce or otherwise negate an impedance of inductor M₁₂. Further, as the combined impedance of inductor M₁₂, decoupling capacitor C_{d12}, and ring impedance Zᵣ₁₂ is decreased, resistance R₁₂ is also decreased. Hence, decoupling capacitor C_{d12} and ring impedance Zᵣ₁₂ may be employed to decouple RF coil element CE₁ and RF coil element CE₂.

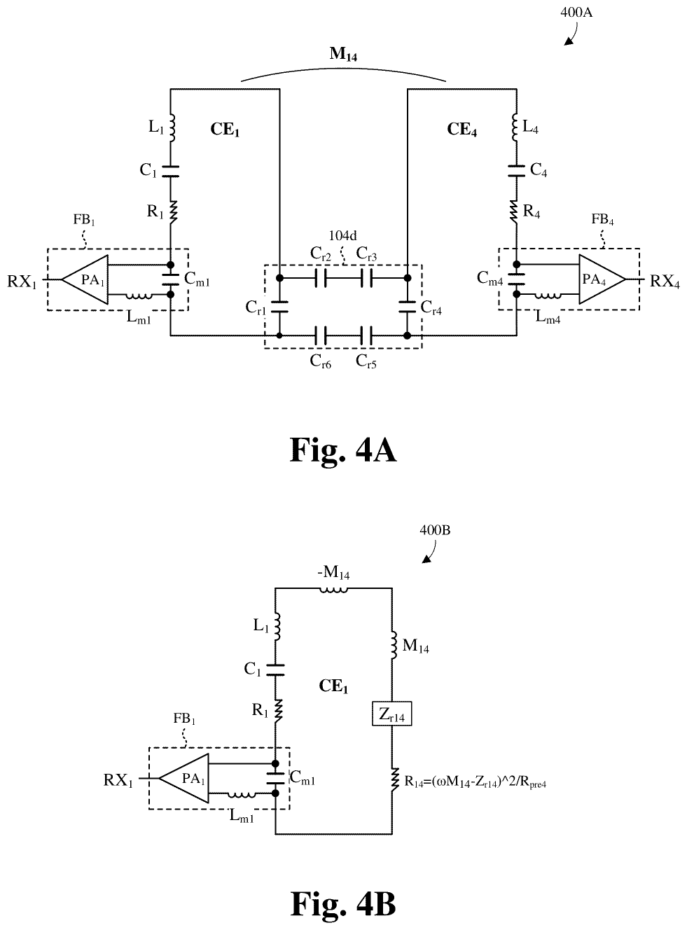

With reference to FIGS. 4A and 4B, simplified diagrams 400A, 400B of some embodiments of a pair of non-directly neighboring RF coil elements CE₁, CE₄ in the multi-row MRI RF coil 102 of FIG. 1 are provided to illustrate decoupling of the pair of the non-directly neighboring RF coil elements. While RF coil element CE₁ and RF coil element CE₄ are illustrated, other non-directly neighboring RF coil elements are amenable.

Focusing on FIG. 4A, RF coil element CE₁ is as in FIG. 3A and is coupled to RF coil element CE₄ by mutual inductance M₁₄. As seen hereafter, the decoupling ring 104d is tuned to minimize or negate mutual inductance M₁₄.

Similar to RF coil element CE₁, RF coil element CE₄ comprises capacitor Cᵣ₄ on the decoupling ring 104d, as well as inductor L₄, capacitor C₄, resistor R₄, and feed board FB₄. Inductor L₄ may correspond to inductance of conductive traces of RF coil element CE₄. Capacitor C₄ may correspond to tuning capacitor C₁₄ in FIG. 1. Resistor R₄ may correspond to coil loss. Feed board FB₄ is configured to output receive signal RX₄ and may, for example, be as its counterpart is described with regard to FIG. 2. Further, feed board FB₄ comprises matching capacitor Cₘ₄, matching inductor Lₘ₄, and preamplifier PA₄.

Focusing on FIG. 4B, the decoupling ring 104d and RF coil element CE₄ are simplified as described with regard to FIGS. 3B-3D. However, in contrast with FIGS. 3B-3D, there is no decoupling capacitor shared between the two RF coil elements. Hence, mutual inductance M₁₄ is minimized or negated by ring impedance Zᵣ₁₄ alone.

Based on the foregoing, direct and non-direct neighbors in the multi-row MRI RF coil 102 of FIG. 1 may be decoupled by appropriately tuning values for the plurality of ring capacitors 112 and the plurality of decoupling capacitors 118. Such tuning may be achieved by trial and error or through minimization of resistance Rᵢ for each RF coil element, where i is an integer index for the RF coil element and resistance Rᵢ is as in Eq. 5.

$${R}_{i} = {\sum }_{{j = 1}_{j \neq i}}^{N} \frac{{( ω {M}_{ij} - {Z}_{ij} )}^{2}}{{R}_{prej}} \qquad Eq . 5$$

Within Eq. 5, N is a total number of RF coil elements on the decoupling ring 104d, i and j are integer indexes representing RF coil elements, Mᵢⱼ is mutual inductance between the RF coil elements represented by i and j, and Rₚᵣₑⱼ is the preamplifier resistance for the RF coil element represented by j. Further, impedance Zᵢⱼ is represented by Eq. 6, which notably varies depending on whether RF coil elements directly neighbor or non-directly neighbor.

$${Z}_{ij} = \{ \begin{matrix}{Z}_{rij} & for non - direct neighbors \\ {Z}_{rij} + \frac{1}{ω {C}_{dij}} & for direct neibhbors\end{matrix} \qquad Eq . 6$$

Within Eq. 6, C_{dij} represents a decoupling capacitor and Zᵣᵢⱼ represents the simplified ring impedance shared by the RF coil elements represented by i and j. In some embodiments, ring impedance Zᵣᵢⱼ may be approximated by Eq. 7, where

$${Z}_{Cri} = \frac{1}{ω {C}_{ri}} .$$

$${Z}_{r 12} = \frac{{Z}_{Cri} {Z}_{Crj}}{{\sum }_{k = 1}^{N} {Z}_{Crk}} \qquad Eq . 7$$

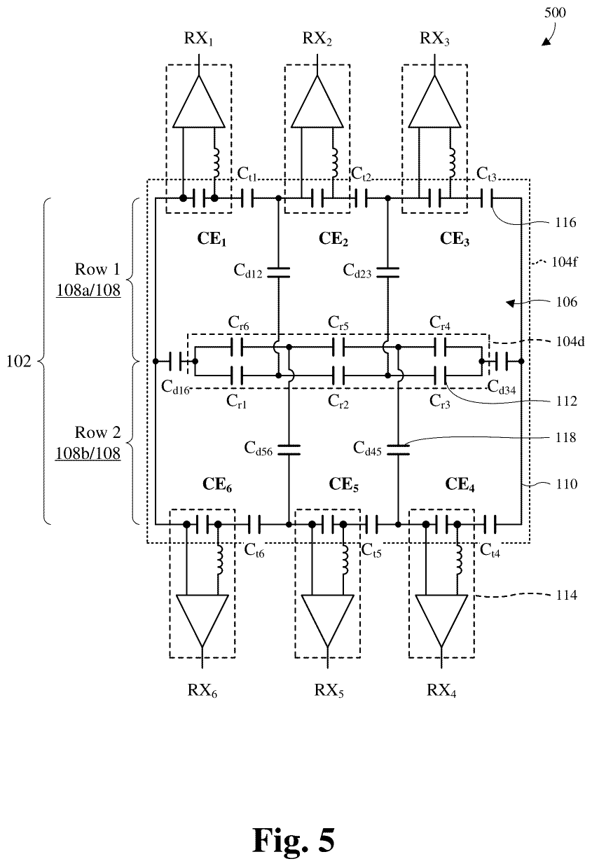

With reference to FIG. 5, a more detailed diagram 500 of some embodiments of the multi-row MRI RF coil 102 of FIG. 1 is provided in which the plurality of feed boards 114 are each individually as their counterpart is illustrated and described in FIG. 2.

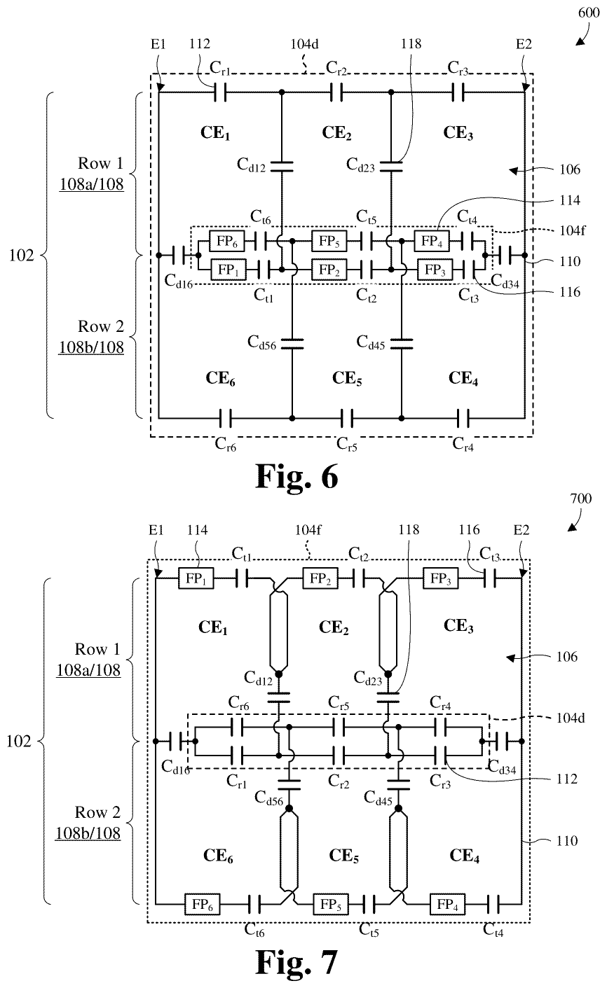

With reference to FIG. 6, a diagram 600 of some alternative embodiments of the multi-row MRI RF coil 102 of FIG. 1 is provided in which locations of the decoupling ring 104d and the feed ring 104f are switched. The decoupling ring 104d is at a periphery of the multi-row MRI RF coil 102 and the feed ring 104f is at an overlap between the plurality of rows 108. Hence, in contrast with FIG. 1, the decoupling ring 104d surrounds the feed ring 104f.

In view of FIGS. 1 and 6, the plurality of RF coil elements 106 are chained together to form a continuous inner ring and a continuous outer ring. Either one of the continuous inner and outer rings may be employed as the decoupling ring 104d and the other one of the continuous inner and outer rings may be employed as the feed ring 104f.

With reference to FIG. 7, a diagram 700 of some alternative embodiments of the multi-row MRI RF coil 102 of FIG. 1 is provided in which overlap decoupling is employed within the plurality of rows 108. For each pair of RF coil elements directly neighboring within a row, the RF coil elements of that pair of RF coil elements are overlapped to reduce coupling between the RF coil elements of that pair of RF coil elements.

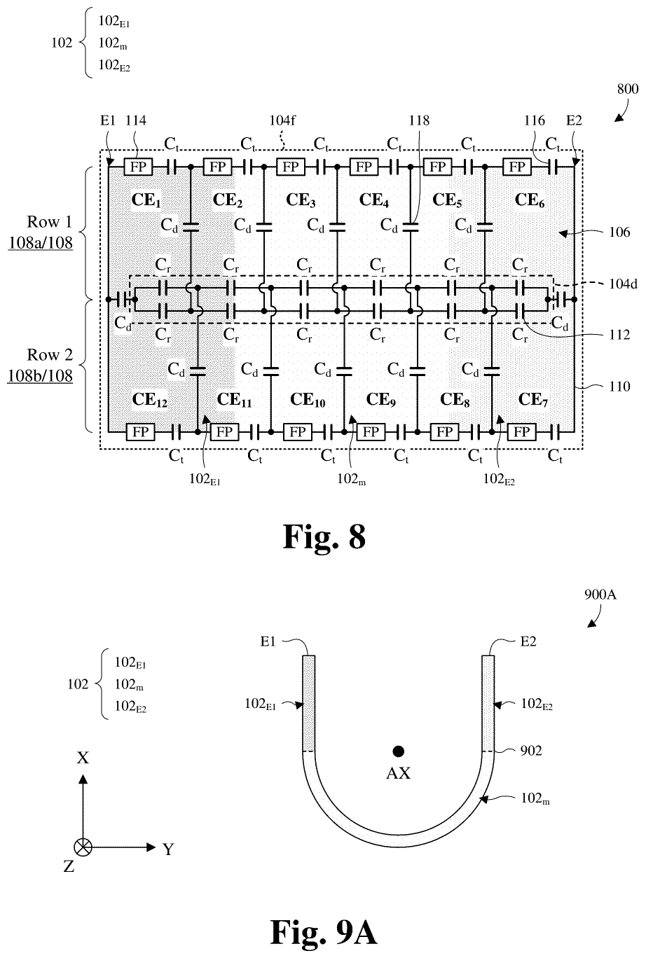

With reference to FIG. 8, a diagram 800 of some alternative embodiments of the multi-row MRI RF coil 102 of FIG. 1 is provided in which the multi-row MR RF coil 102 has additional coil elements. Particularly, each of the plurality of rows 108 has six RF coil elements instead of three RF coil elements. In alternative embodiments, each of the plurality of rows 108 may have more RF coil elements or less RF coil elements.

Additionally, the multi-row MRI RF coil 102 includes a plurality of different regions, which are highlighted by different background patterns. The plurality of different regions include a first end region 102_{E1}, a second end region 102_{E2}, and a middle region 102ₘ. The first and second end regions 102_{E1}, 102_{E2} are respectively at the first and second ends E1 and E2 of the multi-row MRI RF coil 102. Further, the middle region 102ₘ is between and borders the first and second end regions 102_{E1}, 102_{E2}.

With reference to FIGS. 9A and 9B, various diagrams 900A, 900B of some embodiments of a former 902 on which the multi-row MRI RF coil 102 of FIG. 8 is arranged are provided. FIG. 9A provides an axial diagram 900A of the former 902 along an axis AX, whereas FIG. 9B provides a perspective diagram 900B of the former 902.

The former 902 has a U-shaped profile and extends circumferentially around the axis AX. In some embodiments, the axis AX extends in the B₀ field direction during MRI. Because the multi-row MRI RF coil 102 is arranged on the former 902, the multi-row MRI RF coil 102 takes on the shape of the former 902. Hence, the multi-row RF coil 102 has a U-shaped profile and extends circumferentially around the axis AX. The different background patterns on the former 902 correspond to the plurality of different regions of the multi-row MRI RF coil 102 in FIG. 8 (e.g., the first and second end regions 102_{E1} and the middle region 102ₘ) and provide an example of how the multi-row MRI RF coil 102 is arranged on the former 902.

In some embodiments, the axis AX extends in a Z dimension and/or the plurality of rows 108 of the multi-row MRI RF coil 102 (see FIG. 8) are spaced from each other in the Z dimension. Further, in some embodiments, the plurality of rows 108 extend circumferentially around the axis AX in an X-Y plane (e.g., a plane in an X dimension and a Y dimension).

In some embodiments, the former 902 is one integral mechanical piece and/or is rigid. In other embodiments, the former 902 comprises both rigid and flexible mechanical pieces. For example, the former 902 may comprise a rigid piece on which the middle region 102ₘ of the multi-row MRI RF coil 102 is arranged and may further comprise a pair of flexible pieces extending from opposite sides of the rigid piece and on which the first and second end regions 102_{E1}, 102_{E2} of the multi-row MRI RF coil 102 are respectively arranged. This flexibility may, in turn, enhance the mechanical fit of the multi-row MRI RF coil 102 around a scan object (e.g., a foot and/or ankle anatomy or a hand and/or wrist anatomy).

With reference to FIG. 10, an axial diagram 1000 of some alternative embodiments of the former 902 of FIGS. 9A and 9B is provided in which the former 902 and the multi-row MRI RF coil 102 have a C shape. The C shape may be extended along the axis AX (e.g., in the Z dimension) in a manner similar to that shown for the U shape of FIG. 9B.

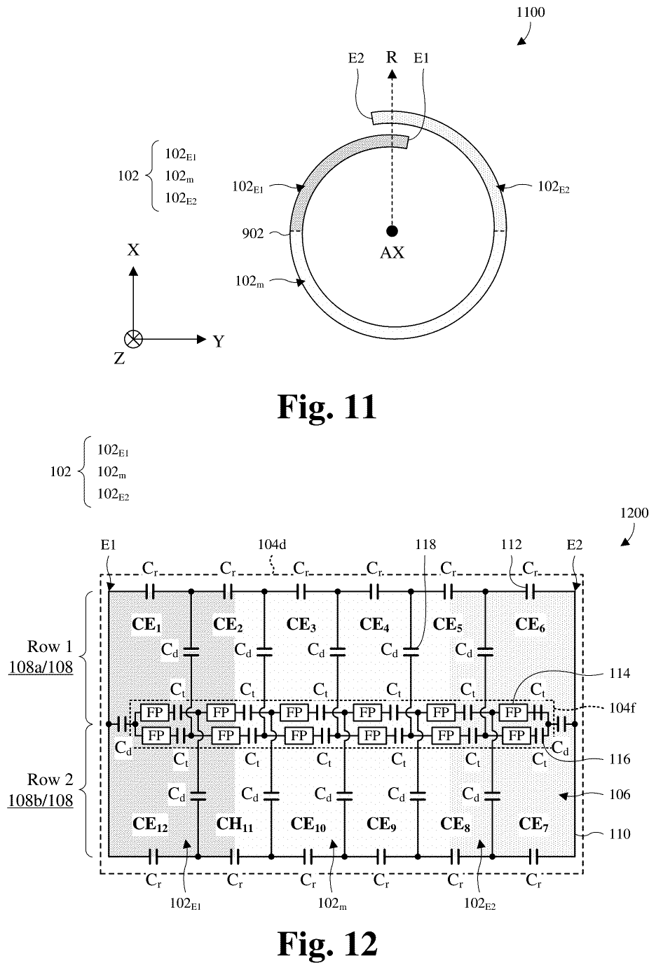

With reference to FIG. 11, an axial diagram 1100 of some alternative embodiments of the former 902 of FIGS. 9A and 9B is provided in which the former 902 and the multi-row MRI RF coil 102 have an O shape. The former 902 and the multi-row MRI RF coil 102 extend circumferentially around the axis AX, and the first and second end regions 102_{E1}, 102_{E2} overlap along a radially-extending axis R. The O shape may be extended along the axis AX (e.g., in the Z dimension) in a manner similar to that shown for the U shape of FIG. 9B.

With reference to FIG. 12, a diagram 1200 of some alternative embodiments of the multi-row MRI RF coil 102 of FIG. 8 is provided in which locations of the decoupling ring 104d and the feed ring 104f are switched. The decoupling ring 104d is at a periphery of the multi-row MRI RF coil 102 and the feed ring 104f is at an overlap between the plurality of rows 108. Hence, in contrast with FIG. 8, the decoupling ring 104d surrounds the feed ring 104f.

With reference to FIG. 13, a diagram 1300 of some alternative embodiments of the multi-row MRI RF coil 102 coil of FIG. 8 is provided in which the plurality of rows 108 are offset from each other along individual lengths of the plurality of rows 108. As such, ends of the first row 108a are offset from ends of the second row 108b along the individual lengths. In contrast, the plurality of rows 108 are substantially aligned in FIG. 8.

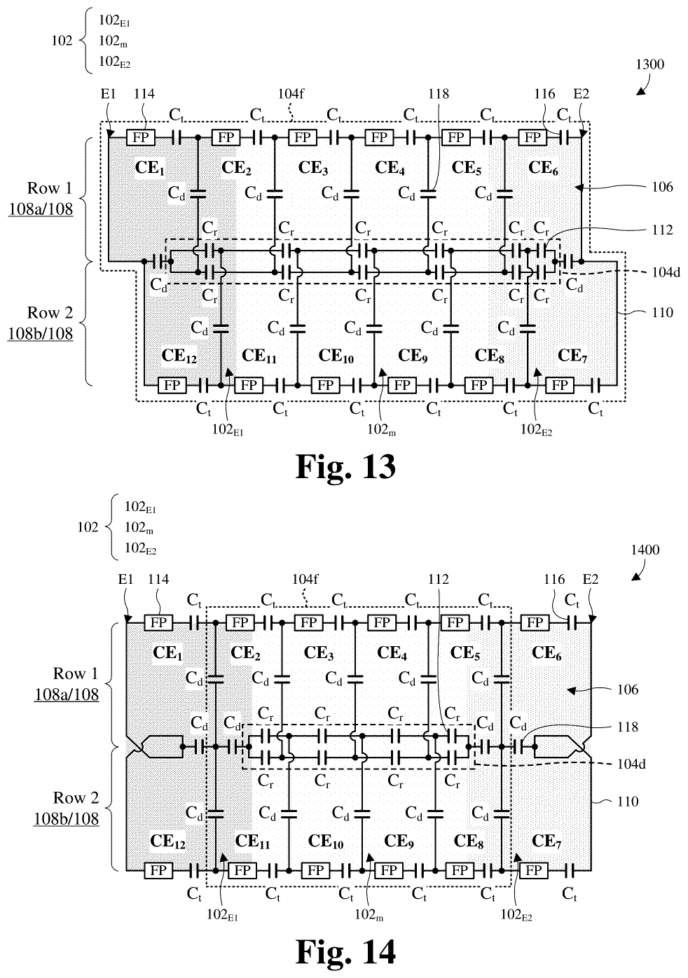

With reference to FIG. 14, a diagram 1400 of some alternative embodiments of the multi-row MRI RF coil 102 of FIG. 8 is provided in which the decoupling ring 104d spans fewer than all RF coil elements. Particularly, the decoupling ring 104d includes RF coil elements at the middle region 102m and excludes RF coil elements at the first and second end regions 102_{E1}, 102_{E2}. In alternative embodiments, the decoupling ring 104d may include a different set of RF coil elements and exclude a different set of RF coil elements.

As previously discussed, the multi-row MRI RF coil 102 may be arranged on a former (e.g., the former 902 of FIGS. 9A and 9B). Further, the former may comprise a rigid piece on which the middle region 102m of the multi-row MRI RF coil 102 is arranged and may further comprise a pair of flexible pieces extending from opposite sides of the rigid piece and on which the first and second end regions 102_{E1}, 102_{E2} of the multi-row MRI RF coil 102 are respectively arranged. Wholly or mostly localizing the decoupling ring 104d to the middle region 102m may enhance the flexibility of the multi-row MRI RF coil 102, which may enhance a mechanical fit of the multi-row MRI RF coil 102 around a scan object.

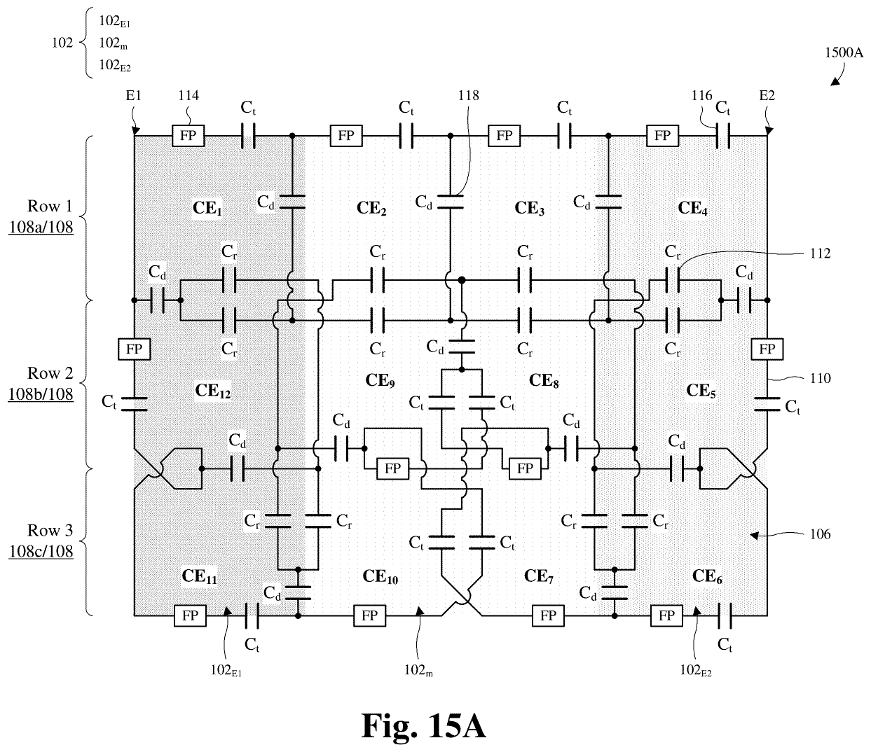

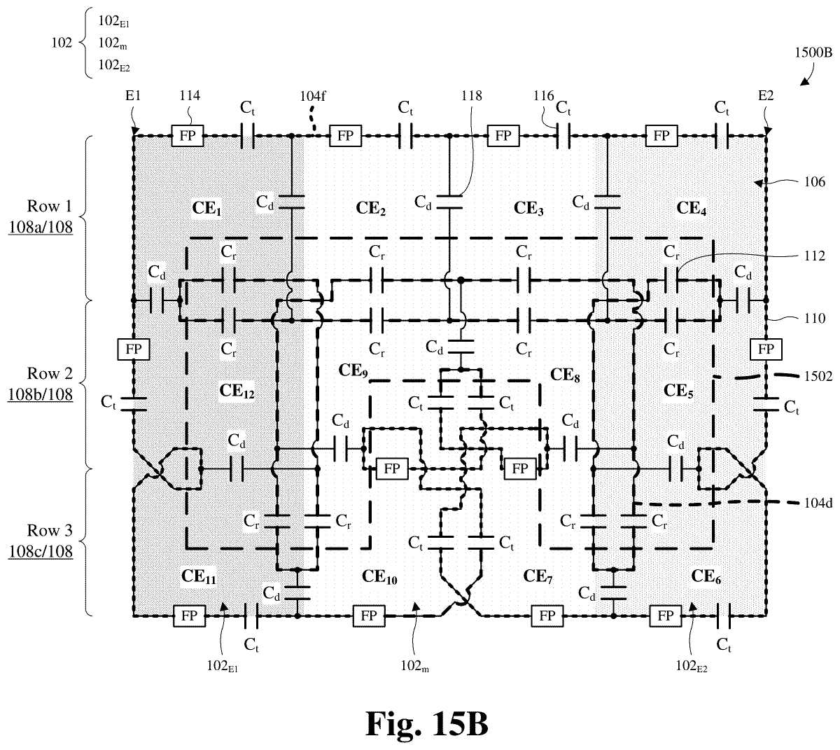

With reference to FIGS. 15A and 15B, various diagrams 1500A, 1500B of some alternative embodiments of the multi-row MRI RF coil 102 of FIG. 8 are provided in which the multi-row MRI RF coil 102 includes a third row 108c. Additionally, each of the plurality of rows 108 have four RF coil elements instead of six RF coil elements. Additional rows may enhance MRI (e.g., via additional acceleration). In alternative embodiments, the multi-row MRI RF coil 102 may include four or more rows and/or each of the plurality or rows 108 may have more or less RF coil elements. FIGS. 15A and 15B illustrate the multi-row MRI RF coil 102 with and without the decoupling ring 104d and the feed ring 104f being labeled.

To understand how the decoupling ring 104d is created with three or more rows, all direct neighboring RF coil elements are daisy chained together to create a one-row-like continuous structure demarcated by a coil-element ring 1502 (see FIG. 15B). The coil-element ring 1502 is a continuous non-regular shape loop that connects all direct neighboring RF coil elements together (e.g., it connects RF coil elements 1, 2, 3, 4, 5, 6, 7, 8, 9, 10, 11, and 12 and comes back to RF coil element 1). With this one-row-like structure, there are two built-in continuous rings, the decoupling ring 104d and the feed ring 104f, that daisy chain all RF coil elements together. The same daisy chain approach can be extended for additional rows.

The decoupling ring approach according to aspects of the present disclosure may improve the decoupling among all RF coil elements on the decoupling ring 104d. However, this doesn't mean that all RF coil elements need to be on the decoupling ring 104d. For example, as seen in FIG. 14, RF coil elements may be excluded from the decoupling ring 104d to improve coil flexibility. As another example, as seen hereafter, RF coil elements may be excluded from the decoupling ring 104d if not at the SNR critical area.

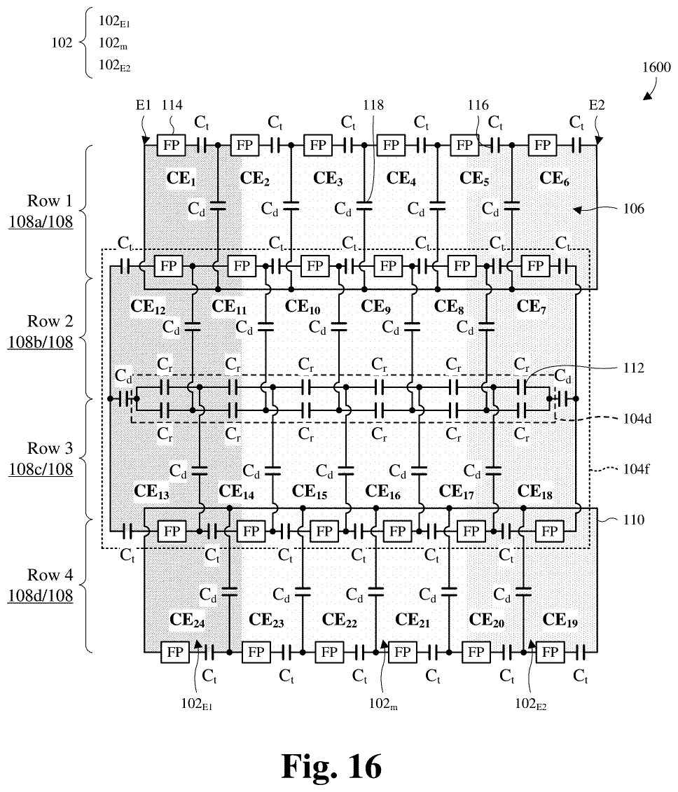

With reference to FIG. 16, a diagram 1600 of some alternative embodiments of the multi-row MRI RF coil 102 of FIG. 8 is provided in which the multi-row MRI RF coil 102 has four rows and the decoupling ring 104d only spans two middle rows. Particularly, the multi-row MRI RF coil 102 may further comprise a third row 108c and a fourth row 108d, wherein the second and third rows 108b, 108c are between and respectively border the first and fourth rows 108a, 108d. Further, the decoupling ring 104d may couple to RF coil elements of the second and third rows 108b, 108c but not to RF coil elements of the first and fourth rows 108a, 108d.

The first and fourth rows 108a, 108d may be outside the SNR critical area, whereby the decoupling ring 104d may be omitted from the first and fourth rows 108a, 108d. Instead, the first and fourth rows 108a, 108d may rely upon overlaps respectively with the second and third rows 108b, 108c and decoupling capacitors (e.g., C_{d}) for decoupling.

Thus far, the plurality of RF coil elements 106 have had individual loop shapes. However, besides using the loop, the saddle and other suitable shapes may be used for the one, some, or all of the plurality of RF coil elements 106. Further, while the plurality of rows 108 within any preceding figure have thus far shared a common number of RF coil elements, different rows may have different numbers of RF coil elements. For example, instead of each row having six RF coil elements, one row may have six RF coil elements and another row may have four RF coil elements or five RF coil elements.

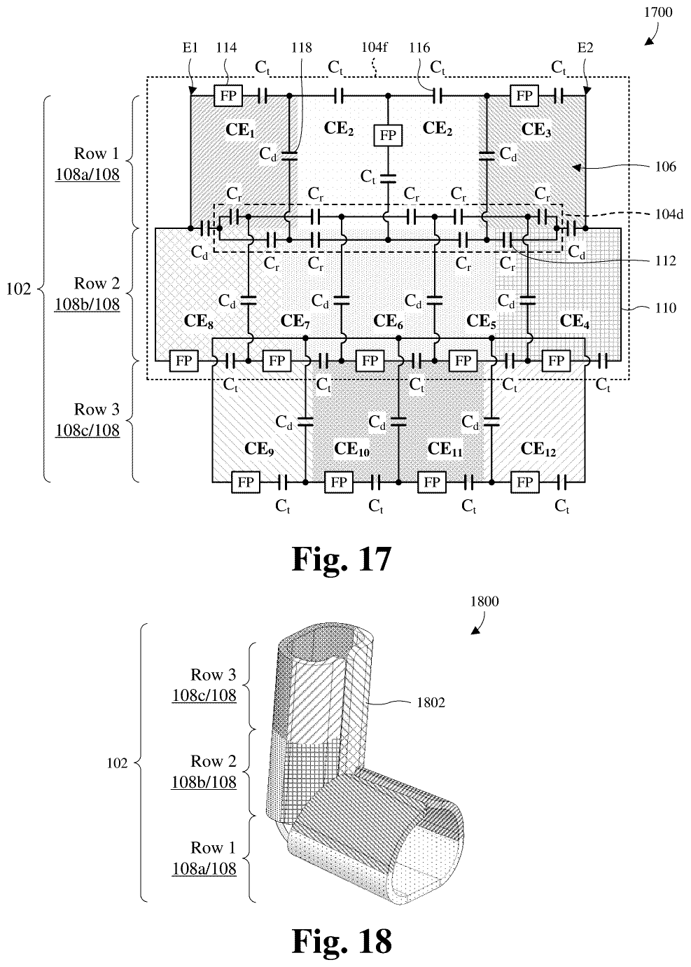

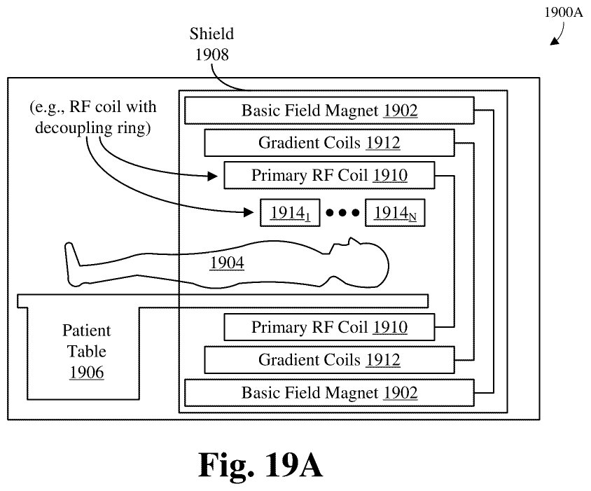

With reference to FIG. 17, a diagram 1700 of some alternative embodiments of the multi-row MRI RF coil 102 of FIG. 8 is provided in which the multi-row MRI RF coil 102 has a saddle-shaped RF coil element. Further, the multi-row MRI RF coil 102 further includes a third row 108c and corresponds to a foot-ankle coil.

The first row 108a corresponds to a foot section of the multi-row MRI RF coil 102. Since the foot bottom directly faces the B₀ field during MRI, a loop shape may be improper. Therefore, the first row 108a has three RF coil elements, including coil element CE₁, coil element CE₂, and coil element CE₃. Coil element CE₁ and coil element CE₃ are loops and coil element CE₂ is a saddle with its B₁ field perpendicular to the B₀ field. The second row 108b corresponds to a heel and ankle section of the multi-row MRI RF coil 102 and includes five loops. Further, the third row 108c corresponds to an Achilles tendon section of the multi-row MRI RF coil 102 and includes four loops.

Since the first and second rows 108a, 108b are likely coupling with each other, the decoupling ring 104d may be used to decouple all RF coil elements in the first and second rows 108a, 108b for an improved SNR. Further, the third row 108c may be outside the SNR critical area, whereby it may be omitted from the decoupling ring 104d.

While FIG. 6 illustrates a modification to FIG. 1 in which the feed ring 104f and the decoupling ring 104d swap locations, it is to be appreciated that this modification is applicable to any of FIGS. 5, 7, 8, 13, 14, 15A, 15B, 16, and 17. While FIG. 7 illustrates a modification to FIG. 1 in which the plurality of RF coil elements 106 overlap within a row, it is to be appreciated that this modification is applicable to any of FIGS. 5, 8, 12-4, 15A, 15B, 16, and 17. While FIGS. 9A, 9B, 10, and 11 illustrate the multi-row MRI RF coil 102 of FIG. 8 as being arranged on different embodiments of the former 902, it is to be appreciated that the multi-row MRI RF coil 102 of any of FIGS. 12-14, 15A, 15B, and 16 may instead be arranged on the different embodiments of the former 902. While FIG. 13 illustrates a modification to FIG. 8 in which the plurality of rows 108 are misaligned, it is to be appreciated that this modification is applicable to any of FIGS. 1, 5-7, 12, 14, 15A, 15B, 16, and 17. While FIG. 14 illustrates a modification to FIG. 8 in which the decoupling ring 104d spans fewer than all RF coil elements, it is to be appreciated that this modification is applicable to any of FIGS. 1, 5-7, 12, 13, 15A, 15B, 16, and 17.

With reference to FIG. 18, a perspective view 1800 of some embodiments of a foot-ankle former 1802 on which the multi-row MRI RF coil 102 of FIG. 17 is arranged is provided. The multi-row MRI RF coil 102 has a plurality of different background patterns demarcating a plurality of different regions of the multi-row MRI RF coil 102. The different background patterns are the same background patterns in FIG. 17 and correspond to the same regions of the multi-row MRI RF coil 102 in FIG. 17. Therefore, the different background patterns are employed to illustrate how the multi-row MRI RF coil 102 is arranged on the foot-ankle former 1802. Other arrangements are, however, amenable.

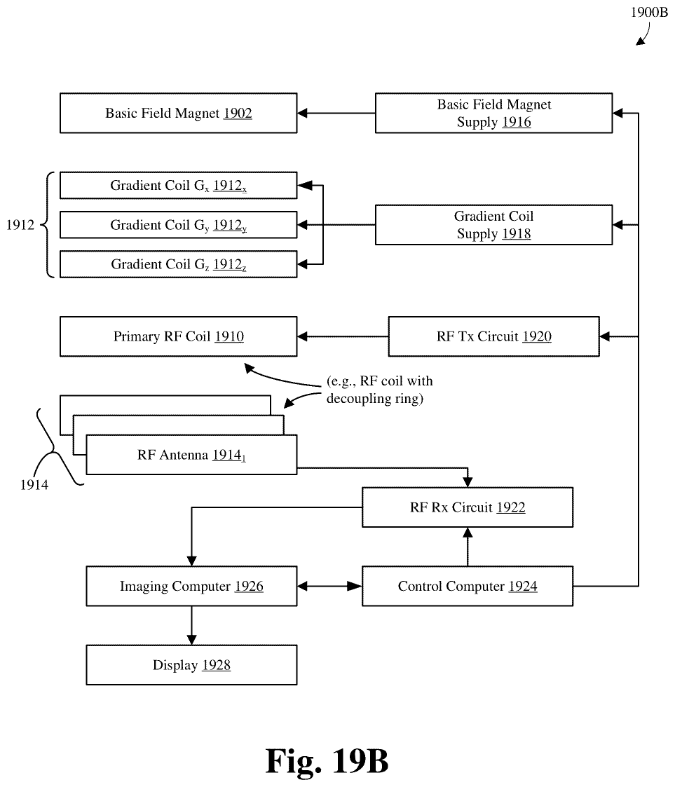

With reference to FIGS. 19A and 19B, various diagrams 1900A, 1900B of some embodiments of an MRI system comprising a multi-row MRI RF coil with a discontinuous cylindrical-like shape and a decoupling ring are provided. FIG. 19A illustrates a high-level view of the MRI system, and FIG. 19B illustrates a block diagram of the MRI system.

Focusing on FIG. 19A, the MRI system uses RF antennas, in the form of RF coils or RF coil elements, to transmit and receive RF pulses within a magnetic field (e.g., generated by a basic field magnet 1902). The received pulses are used to create images of tissue of a patient 1904 (e.g., positioned on a patient table 1906) to aid in the diagnosis of medical conditions. Generally, a shield 1908 may substantially contain the generated magnetic fields and RF pulses from the surrounding environment of the MRI system.

In some embodiments, the MRI system may employ a primary RF coil 1910 operating in conjunction with gradient coils 1912 as a transmission device. The primary RF coil 1910 may also be referred to as a whole-body coil (WBC). Further, the primary RF coil 1910 may sometimes be used as a receive device. However, the primary RF coil 1910 is intended for imaging large portions of the body. Therefore, a local RF coil may be employed to receive RF pulses from the anatomy undergoing MRI. The local RF coil is smaller than the primary RF coil 1910 and comprises a set of one or more local antennas 1914₁, 1914₂ . . . 1914_{N}.

In some embodiments, the multi-row MRI RF coil 102 in any of FIGS. 1 to 18 may serve as the primary RF coil 1910. In other embodiments, the multi-row MRI RF coil 102 may serve as the smaller local RF coil. For example, RF coil elements 106 of such a multi-row MRI RF coil 102 may correspond to the one or more local antennas 1914₁, 1914₂ . . . 1914_{N}.

Focusing on FIG. 19B, the basic field magnet 1902 is electrically coupled to and controlled, at least partially by, a basic field magnet supply 1916. Further, the gradient coils 1912 are electrically coupled to and controlled, at least partially by, a gradient coil supply 1918. The gradient coils 1912 are configured to emit gradient magnetic fields like Gₓ (e.g., via an associated gradient coil 1912ₓ), G_{y} (e.g., via an associated gradient coil 1912_{y}), and G_{z} (e.g., via an associated gradient coil 1912_{z}). In some examples, the timing, strength, and orientation of the gradient magnetic fields can be controlled and adapted during an MRI procedure.

The primary RF coil 1910 is configured to transmit RF pulses into a scan object in response to one or more transmit signals from an RF transmit (Tx) circuit 1920. A local RF coil 1914 smaller than the primary RF coil 1910 is configured to receive resulting magnetic resonance (MR) signals from the scan object and to pass the resulting MR signals to an RF receive (Rx) circuit 1922. The local RF coil 1914 comprises the set of one or more RF antennas 1914₁-19140_{N}.

In alternative embodiments, the primary RF coil 1910 is configured to receive resulting MR signals from the scan object and to pass the resulting MR signals to the RF Rx circuit 1922. This may be in addition to or in place of the local RF coil 1914. Further, in alternative embodiments, the local RF coil 1914 is configured to transmit RF pulses into the scan object in response to one or more transmit signals from the RF Tx circuit 1920. This may be in addition to or in place of the primary RF coil 1910.

An RF coil configured solely to generate RF pulses can also be referred to herein as a Tx coil, while an RF coil configured solely to receive resulting MR signals can be referred to herein as an Rx coil. An RF coil configured to both generate RF pulses and receive resulting MR signals can be referred to herein as a Tx/Rx coil. Therefore, the local RF coil 1914 may be regarded as a Rx coil, a Tx coil, or a Tx/Rx coil depending on how it is configured. The same may be said for the primary RF coil 1910.

The primary RF coil 1910 may be or comprise any embodiment of the multi-row MRI RF coil 102 described or illustrated within the present application. Similarly, the local RF coil 1914 may be or comprise any embodiment of the multi-row MRI RF coil 102 described or illustrated within the present application. Further, the set of one or more RF antennas 1914₁-1914_{N} may correspond to the plurality of RF coil elements 106 for any embodiment of the multi-row MRI RF coil 102 described or illustrated within the present application.

In some embodiments in which the multi-row MRI RF coil 102 is employed as a Tx coil (e.g., via the primary RF coil 1910 or the local RF coil 1914), the multi-row MRI RF coil 102 may be a pTx RF coil. In some embodiments in which the multi-row MRI RF coil 102 is employed as a Rx coil (e.g., via the primary RF coil 1910 or the local RF coil 1914), the multi-row MRI RF coil 102 may be a phased array receive coil. The enhanced decoupling between RF coil elements (e.g., from the decoupling ring 104d, the plurality of decoupling capacitors 118, and the row overlap) facilitates use of multi-row MRI RF coil 102 as above.

In some embodiments, the local RF coil 1914 is wirelessly electrically coupled to the RF Rx circuit 1922 and/or the RF Tx circuit 1920 via inductive coupling to the primary RF coil 1910. In such embodiments, the primary RF coil 1910 may be directly wired to the RF Rx circuit 1922 and/or the RF Tx circuit 1920, and the local RF coil 1914 may be wirelessly connected to the primary RF coil 1910. In other embodiments, the local RF coil 1914 is directly wired to the RF Rx circuit 1922 and/or the RF Tx circuit 1920.

The gradient coils supply 1918 and the RF Tx circuit 1920 can be controlled, at least in part, by a control computer 1924. The MR signals received from local RF coil 1914 can be employed to generate an image, and thus can be subject to a transformation process like a two-dimensional fast Fourier transform (FFT) that generates pixelated image data. The transformation can be performed by an image computer 1926 or other similar processing device. The image data can then be shown on a display 1928. The RF Rx circuit 1922 can be connected with the control computer 1924 or the image computer 1926.

While FIGS. 19A and 19B illustrate an example MRI system that includes various components connected in various ways, it is to be appreciated that other MRI systems can include other components connected in other ways and can be employed in connection with various embodiments discussed herein.

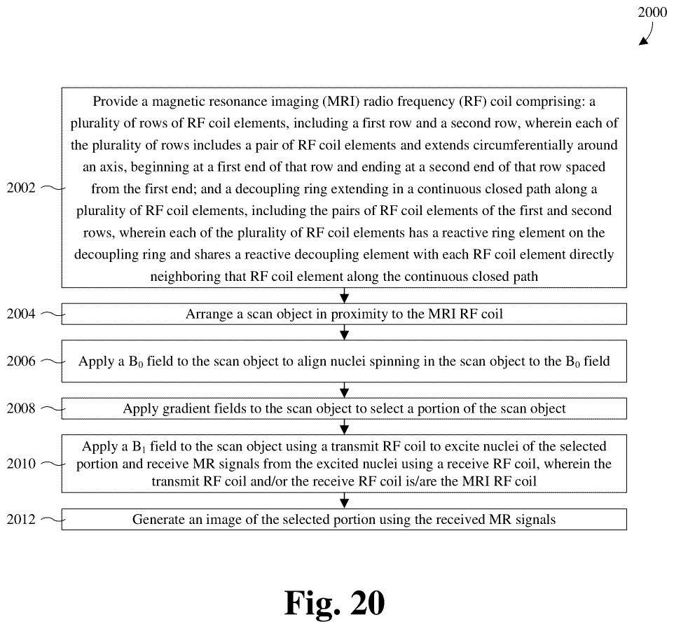

With reference to FIG. 20, a block diagram 2000 of some embodiments of a method for MRI in accordance with some aspects of the present disclosure is provided. The method may, for example, be employed using the MRI system in FIGS. 19A and 19B.

At step 2002, a MRI RF coil according to aspects of the present disclosure is provided. The MRI RF coil may, for example, be configured according to any embodiment of the multi-row MRI RF coil 102 described or illustrated within the present application.

In some embodiments, the MRI RF coil comprises a plurality of rows of RF coil elements, including a first row and a second row. Each of the plurality of rows includes a pair of RF coil elements and extends circumferentially around an axis, beginning at a first end of that row and ending at a second end of that row spaced from the first end. Further, the MRI RF coil comprises a decoupling ring extending in a continuous closed path along a plurality of RF coil elements, including the pair of RF coil elements of the first row and the pair of RF coil elements of the second row. Each of the plurality of RF coil elements has a reactive ring element on the decoupling ring and shares a reactive decoupling element with each RF coil element directly neighboring that RF coil element along the continuous closed path.

At step 2004, a scan object is arranged in proximity to the MRI RF coil. For example, the scan object is arranged in the MRI RF coil. As another example, the MRI RF coil is arranged on and around the scan object.

At step 2006, a B₀ field is applied to the scan object to align nuclei spinning in the scan object to the B₀ field. For example, the basic field magnetic 1902 of FIGS. 19A and 19B may generate the B₀ field.

At step 2008, gradient fields are applied to the scan object to select a portion of the scan object. For example, the gradient coils 1912 of FIGS. 19A and 19B may generate the gradient fields.

At step 2010, a B₁ field is applied to the scan object using a transmit RF coil to excite nuclei of the selected portion. Further, MR signals are received from the excited nuclei using a receive RF coil. The transmit RF coil and/or the receive RF coil is/are the MRI RF coil.

At step 2012, an image of the selected portion is generated using the received MR signals. For example, the imaging computer 1926 in FIG. 19B may generate the image.

While the block diagram 2000 of FIG. 20 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts may be required to implement one or more aspects or embodiments of the description herein, and one or more of the acts depicted herein may be carried out in one or more separate acts and/or phases.

In view of the foregoing, some embodiments of the present disclosure provide a MRI RF coil, including: a plurality of rows of RF coil elements, including a first row and a second row, wherein each of the plurality of rows includes a pair of RF coil elements, the first row extends circumferentially around an axis, beginning at a first end of the first row and ending at a second end of the first row that is disconnected from the first end, and the pair of RF coil elements of the first row directly neighbor in the first row and share a conductive trace and a reactive decoupling element; and a decoupling ring extending in a continuous closed path and configured to decouple a plurality of RF coil elements, including the pair of RF coil elements of the first row and the pair RF coil elements of the second row, wherein each of the plurality of RF coil elements includes a reactive ring element on the decoupling ring. In some embodiments, the plurality of RF coil elements include all RF coil elements in the plurality of rows. In some embodiments, the plurality of RF coil elements exclude RF coil elements respectively at the first and second ends of the first row and include remaining RF coil elements in the first row. In some embodiments, the second row overlaps with the first row along the axis at an overlap region, wherein the decoupling ring is localized to the overlap region. In some embodiments, the MRI RF coil further includes a feed ring spaced from the decoupling ring and extending in an additional continuous closed path around the plurality of RF coil elements and the decoupling ring, wherein the plurality of RF coil elements each include a feed board on the feed ring. In some embodiments, the MRI RF coil further includes a feed ring extending in an additional continuous closed path, wherein the plurality of RF coil elements each include a feed board on the feed ring, and wherein the decoupling ring is spaced from and surrounds the feed ring. In some embodiments, the decoupling ring is localized to a periphery of the plurality of RF coil elements. In some embodiments, the plurality of rows include a third row, wherein the second row is between and overlaps with the first and third rows, and wherein the decoupling ring is at the first and second rows and is spaced from the third row, which is spaced from the first and second rows. In some embodiments, a total number of RF coil elements in the first row is different than a total number of RF coil elements in the second row.

In some embodiments, the present disclosure provides a MRI system including an MRI RF coil, wherein the MRI RF coil includes: a plurality of rows of RF coil elements, including a first row and a second row, wherein each of the plurality of rows includes a pair of RF coil elements and extends circumferentially around an axis, beginning at a first end of that row and ending at a second end of that row, the pair of RF coil elements of the first row are spaced from each other and are respectively at the first end of the first row and the second end of the first row, and each RF coil element of the first row shares a reactive decoupling element with each directly neighboring RF coil element of the first row; and a decoupling ring extending in a continuous closed path along a plurality of RF coil elements, including the pairs of RF coil elements of the first and second rows, wherein the decoupling ring includes a reactive ring portion of each of the plurality of RF coil elements. In some embodiments, the reactive ring portion of each of the plurality of RF coil elements is between and directly electrically coupled to a pair of reactive ring portions of two other RF coil elements. In some embodiments, the reactive ring portion of each of the plurality of RF coil elements consists essentially of a conductive trace and one or more reactive elements that are in series. In some embodiments, the first row is C shaped or U shaped. In some embodiments, the first row is O shaped with the first and second ends of the first row being disconnected. In some embodiments, the MRI RF coil further includes a feed ring extending in an additional continuous closed path and including a feed ring portion of each of the plurality of RF coil elements, wherein the feed ring portion of each of the plurality of RF coil elements includes a feed board, which includes a matching circuit and a low input impedance preamplifier. In some embodiments, the first and second ends of the first row are circumferentially offset from the first and second ends of the second row. In some embodiments, the first row includes an additional RF coil element between the pair of RF coil elements of the first row, wherein the pair of RF coil elements are loop shaped, and wherein the additional RF coil element is a saddle shaped.

In some embodiments, the present disclosure provides a method for MRI, including: providing an MRI RF coil including: a plurality of rows of RF coil elements, including a first row and a second row, wherein each of the plurality of rows includes a pair of RF coil elements and extends circumferentially around an axis, beginning at a first end of that row and ending at a second end of that row spaced from the first end; and a decoupling ring extending in a continuous closed path along a plurality of RF coil elements, including the pairs of RF coil elements of the first and second rows, wherein each of the plurality of RF coil elements has a reactive ring element on the decoupling ring and shares a reactive decoupling element with each RF coil element directly neighboring that RF coil element along the continuous closed path; and performing MRI of a scan object, wherein the performing includes exciting nuclei in the scan object at a working frequency and receiving magnetic resonance (MR) signals from the scan object, and wherein the exciting and/or the receiving are performed using the MRI RF coil. In some embodiments, the exciting includes driving the MRI RF coil in a pTx mode. In some embodiments, the receiving is performed using the MRI RF coil in a phased array receive mode.

The following includes definitions of selected terms employed herein. The definitions include various examples or forms of components that fall within the scope of a term and that may be used for implementation. The examples are not intended to be limiting. Both singular and plural forms of terms may be within the definitions.

The terminology used herein is for the purpose of describing particular embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which embodiments belong. It will be further understood that terms (e.g., those defined in commonly used dictionaries) should be interpreted as having a meaning that is consistent with their meaning in the context of the relevant art and will not be interpreted in an idealized or overly formal sense unless expressly so defined herein.

In the above description, some components may be displayed in multiple figures carrying the same reference signs and/or names but may not be described multiple times in detail. A detailed description of a component may then apply to that component for all its occurrences. Further, numerical designations (e.g., first, second, third, etc.) may be used for clarity to distinguish between components of the same type. However, it is to be appreciated that the numerical designation may vary for components displayed in multiple figures, depending upon context. For example, a component referred to as third in one figure, may be referred to as fourth in another figure if another component of the same type already has the designation of third.

The detailed descriptions presented herein may be presented in terms of algorithms and symbolic representations of operations on data bits within a memory. These algorithmic descriptions and representations are used by those skilled in the art to convey the substance of their work to others. An algorithm, here and generally, is conceived to be a sequence of operations that produce a result. The operations may include physical manipulations of physical quantities. Usually, though not necessarily, the physical quantities take the form of electrical or magnetic signals capable of being stored, transferred, combined, compared, otherwise manipulated in a logic, and so on. The physical manipulations create a concrete, tangible, useful, real-world result.

It has proven convenient at times, principally for reasons of common usage, to refer to these signals as bits, values, elements, symbols, characters, terms, numbers, and so on. It should be borne in mind, however, that these and similar terms are to be associated with the appropriate physical quantities and are merely convenient labels applied to these quantities. Unless specifically stated otherwise, it is appreciated that throughout the description, terms including processing, computing, calculating, determining, and so on refer to actions and processes of a computer system, logic, processor, or similar electronic device that manipulates and transforms data represented as physical and/or electronic quantities.

Example methods may be better appreciated with reference to flow diagrams. While for purposes of simplicity of explanation, the illustrated methodologies are shown and described as a series of blocks, it is to be appreciated that the methodologies are not limited by the order of the blocks, as some blocks can occur in different orders and/or concurrently with other blocks from that shown and described. Moreover, less than all the illustrated blocks may be required to implement an example methodology. Blocks may be combined or separated into multiple components. Furthermore, additional and/or alternative methodologies can employ additional, not illustrated blocks.

What is claimed is:

1. A magnetic resonance imaging (MRI) radio frequency (RF) coil, comprising:
a plurality of rows of RF coil elements, including a first row and a second row, wherein each of the plurality of rows includes a pair of RF coil elements,
the first row extends circumferentially around an axis, beginning at a first end of the first row and ending at a second end of the first row that is disconnected from the first end, and
the pair of RF coil elements of the first row directly neighbor in the first row and share a conductive trace and a reactive decoupling element; and
a decoupling ring extending in a continuous closed path and configured to decouple a plurality of RF coil elements, including the pair of RF coil elements of the first row and the pair RF coil elements of the second row, wherein each of the plurality of RF coil elements includes a reactive ring element on the decoupling ring.

2. The MRI RF coil according to claim 1, wherein the plurality of RF coil elements include all RF coil elements in the plurality of rows.

3. The MRI RF coil according to claim 1, wherein the plurality of RF coil elements exclude RF coil elements respectively at the first and second ends of the first row and include remaining RF coil elements in the first row.

4. The MRI RF coil according to claim 1, wherein the second row overlaps with the first row along the axis at an overlap region, and wherein the decoupling ring is localized to the overlap region.

5. The MRI RF coil according to claim 4, further comprising:
a feed ring spaced from the decoupling ring and extending in an additional continuous closed path around the plurality of RF coil elements and the decoupling ring, wherein the plurality of RF coil elements each include a feed board on the feed ring.

6. The MRI RF coil according to claim 1, further comprising:
a feed ring extending in an additional continuous closed path, wherein the plurality of RF coil elements each include a feed board on the feed ring, and wherein the decoupling ring is spaced from and surrounds the feed ring.

7. The MRI RF coil according to claim 6, wherein the decoupling ring is localized to a periphery of the plurality of RF coil elements.

8. The MRI RF coil according to claim 1, wherein the plurality of rows include a third row, wherein the second row is between and overlaps with the first and third rows, and wherein the decoupling ring is at the first and second rows and is spaced from the third row, which is spaced from the first and second rows.

9. The MRI RF coil according to claim 1, wherein a total number of RF coil elements in the first row is different than a total number of RF coil elements in the second row.

10. A magnetic resonance imaging (MRI) system comprising an MRI radio frequency (RF) coil, wherein the MRI RF coil comprises:
a plurality of rows of RF coil elements, including a first row and a second row, wherein each of the plurality of rows includes a pair of RF coil elements and extends circumferentially around an axis, beginning at a first end of that row and ending at a second end of that row,
the pair of RF coil elements of the first row are spaced from each other and are respectively at the first end of the first row and the second end of the first row, and
each RF coil element of the first row shares a reactive decoupling element with each directly neighboring RF coil element of the first row; and
a decoupling ring extending in a continuous closed path along a plurality of RF coil elements, including the pairs of RF coil elements of the first and second rows, wherein the decoupling ring comprises a reactive ring portion of each of the plurality of RF coil elements.

11. The MRI system according to claim 10, wherein the reactive ring portion of each of the plurality of RF coil elements is between and directly electrically coupled to a pair of reactive ring portions of two other RF coil elements.

12. The MRI system according to claim 10, wherein the reactive ring portion of each of the plurality of RF coil elements consists essentially of a conductive trace and one or more reactive elements that are in series.

13. The MRI system according to claim 10, wherein the first row is C shaped or U shaped.

14. The MRI system according to claim 10, wherein the first row is O shaped with the first and second ends of the first row being disconnected.

15. The MRI system according to claim 10, wherein the MRI RF coil further comprises:
a feed ring extending in an additional continuous closed path and comprising a feed ring portion of each of the plurality of RF coil elements, wherein the feed ring portion of each of the plurality of RF coil elements comprises a feed board, which comprises a matching circuit and a low input impedance preamplifier.

16. The MRI system according to claim 10, wherein the first and second ends of the first row are circumferentially offset from the first and second ends of the second row.

17. The MRI system according to claim 10, wherein the first row comprises an additional RF coil element between the pair of RF coil elements of the first row, wherein the pair of RF coil elements are loop shaped, and wherein the additional RF coil element is a saddle shaped.

18. A method for magnetic resonance imaging (MRI), comprising:
providing an MRI radio frequency (RF) coil comprising:
a plurality of rows of RF coil elements, including a first row and a second row, wherein each of the plurality of rows includes a pair of RF coil elements and extends circumferentially around an axis, beginning at a first end of that row and ending at a second end of that row spaced from the first end; and
a decoupling ring extending in a continuous closed path along a plurality of RF coil elements, including the pairs of RF coil elements of the first and second rows, wherein each of the plurality of RF coil elements has a reactive ring element on the decoupling ring and shares a reactive decoupling element with each RF coil element directly neighboring that RF coil element along the continuous closed path; and
performing MRI of a scan object, wherein the performing comprises exciting nuclei in the scan object at a working frequency and receiving magnetic resonance (MR) signals from the scan object, and wherein the exciting and/or the receiving are performed using the MRI RF coil.

19. The method according to claim 18, wherein the exciting comprises driving the MRI RF coil in a parallel transmit (pTx) mode.

20. The method according to claim 18, wherein the receiving is performed using the MRI RF coil in a phased array receive mode.
